(19) United States
(12) Patent Application Publication
(10) Pub. No.: US 2003/0000471 A1
(43) Pub. Date: Jan. 2, 2003

(54) Method and apparatus for manufacturing semiconductor devices

(76) Inventors: Soo-Sik Yoon, Gyeonggi-do (KR); Seung-Dong Kang, Gyeonggi-do (KR); Yu-Dong Lim, Gyeonggi-do (KR); Yong-Kyu Lee, Incheon (KR)

Correspondence Address: LEWIS F. GOULD, JR., DUANE MORRIS LLP, ONE LIBERTY PLACE, PHILADELPHIA, PA, 19103, US

(21) Appl. No.: 10/174,161

(22) Filed: Jun. 18, 2002

(30) Foreign Application Priority Data
Jun. 18, 2001 (KR) 2001-34220
Mar. 13, 2002 (KR) 2002-13591

(51) Int. Cl. C23C 16/00

(52) U.S. Cl. 118/715

(57) ABSTRACT

The present invention provides a thin film deposition apparatus that prevent a wafer from the thermal budget so as to form a thin film without any damages. The thin film deposition apparatus includes a chamber where a wafer is loaded; a gas supplier containing a plurality of gases, the gas supplier connected with the chamber through at least a gas inflow pipe so as to supplying the plurality of gases into the chamber; an airtight reaction room in the chamber where the plurality of gases are reaction with one another so as to form a thin film on the wafer; and a gas pre-treatment device in the gas supplier, the gas pre-treatment device thermal-treating at least one of the plurality of gases at a temperature in the range of more than 300 to less than 2000 degrees centigrade; wherein the gas pre-treatment device is connected to at least a connecting pipe.

This application claims the benefit of Korean Patent Application Nos. 2001-34220 and 2002-13591 filed on Jun. 18, 2001 and on Mar. 13, 2002, respectively, in Korea, which are both hereby incorporated by reference.

### BACKGROUND OF THE INVENTION

1. Field of the Invention

The present invention relates to a deposition method and apparatus, and more particularly, to a method of forming a thin film on a wafer using a CVD (Chemical Vapor Deposition).

2. Description of Related Art

The semiconductor devices, such as a LSI (Large Scale Integrated), a memory IC (Integrated Circuit) and other logic elements, are generally fabricated by repeated depositing and patterning processes. Fabricating the semiconductor devices widely includes epitaxy process, thin film deposition process, diffusion/ion-injection process, photolithography, etching, and so on. Among these fabrication processes, the thin film deposition process is a prerequisite for the semiconductor devices, so the thin film deposition process is essentially required and repeated throughout the manufacture of semiconductor devices.

Generally, the thin films formed by the thin film deposition process are classified into four varieties depending on their use. The first is an oxide film, such as silicon oxide (SiO₂), which is often used for a gate oxidized film or a field oxidized film. The second is a nitride film, such as silicon nitride (Si₃N₄), which serves to insulate conductive layers. Also, the nitride film is used as a passivation layer that protects the underlay layers and as a mask in the diffusion/ion-injection process. The third is a silicon layer, such as a polycrystalline silicon film, which is often used as a gate electrode in substitute for metal. The fourth is a metal layer, which serves to connect the structural elements in the semiconductor devices or acts as an electrode.

The CVD (Chemical Vapor Deposition) will briefly be explained. A wafer is first loaded into the chamber that has an airtight reaction room therein, and then a plurality of source gases are injected into that chamber. Thereafter, the plurality of source gases are reacted with one another in the chamber, and then a thin film is formed on the wafer. Recently, the CVD is often performed under a low pressure to achieve desired step coverage and uniform thickness as well as to avoid contamination due to an atmospheric pressure condition.

FIG. 1 schematically illustrates a thin film deposition apparatus diagram for the CVD according to a conventional art. As shown in FIG. 1, the conventional thin film deposition apparatus includes a chamber 10 and a gas supplier 40. The chamber 10 has an airtight reaction room therein and a wafer 5 is loaded on a chuck 20 inside the airtight reaction room. The gas supplier 40 serves to contain a plurality of source gases that will be introduced into the reaction room of the chamber 10.

The chamber 10 is connected to the gas supplier 40 through a gas inflow pipe 12 so as to receive the source gases through the gas inflow pipe 12. A gas outflow pipe 14 is connected to the bottom of the chamber 10, and a decompression device, such as a pump P, is connected to the chamber 10 through the gas outflow pipe 14.

In the gas supplier 40, there are first and second gas containers 42 and 46 which store first and second gases S1 and S2, respectively. First and second mass flow controllers (MFCs) 44 and 48 are connected to the first and second gas containers 42 and 46, respectively. The first MFC 44 controls the flow rate of first gas S1 and the second MFC 48 controls the flow rate of second gas S2.

Therefore, when the wafer 5 is mounted on the chuck 20, the chamber 10 is made airtight and then the first gas S1 contained in the first gas container 42 is supplied into the chamber 10 by the first MFC 44. At the same time, the second gas S2 contained in the second gas container 46 is supplied into the chamber 10 by the second MFC 48. The first and second gases S1 and S2 react with each other in the airtight reaction room of the chamber 10 so that a reaction product are deposited on the wafer 5 to form a thin film.

In the meantime, the airtight reaction room of the chamber 10 should be kept at a high temperature in order to promote the gas reaction. For the high temperature atmosphere in the airtight reaction room, the chuck 20 includes a heater 22 that heats up the wafer 5 and the airtight reaction room. The atmospheric temperature in the airtight reaction room of the chamber 10 can vary depending on the gases, gas reaction and reaction product. Especially, when the nitride film or oxide film are formed on the wafer 5, the atmosphere of the airtight reaction room should be maintained at a temperature of about 700 degrees centigrade. For the purpose of forming the nitride film or oxide film, one of NH₃, N₂O and O₂ is used as a first gas and either of SiH₄ and Si₂H₆ is used as a second gas. Among these gases, NH₃, N₂O and O₂ are usually very stable chemical compounds so that the atmospheric temperature of about 700 degrees centigrade are required in the airtight reaction room to accelerate the gas reaction.

However, due to the high atmospheric temperature of the airtight reaction room, the wafer 5 is exposed under the high temperature for a relatively long time, and thus the wafer 5 receives serious thermal shock. When the wafer 5 is left under the high temperature, the thin film formed on the wafer 5 is damaged and deteriorated by the impurities. Furthermore, the ion-impurities doped onto the thin film are spoiled. Therefore, the high atmospheric temperature threatens the reliability and stability of the semiconductor devices and then eventually degrades the semiconductor devices. Additionally, the thin film deposition apparatus should have a complicated structure for controlling and maintaining the high atmospheric temperature in the airtight reaction chamber 10. These interrupt the fabrication process of the semiconductor devices.

To overcome the above-mentioned problems, a remote plasma method is researched and developed in these days. According to the remote plasma method, the first and/or second gases are excited into plasma to let the source gases have a low activation energy, and then the activated plasma gas radicals are introduced into the chamber 10. To generate the plasma gas radicals, a Capacitively Coupled Plasma (CCP) generator or an Inductively Coupled Plasma (ICP) generator is applied in positions A and B of FIG. 1. However, the above-mentioned remote plasma generator causes some problems. Namely, the CCP or ICP generator creates sputtering phenomenon or charging damage in the reaction room of the chamber.

Since the charged plasma is difficult to be controlled, the plasma ions collide against the wafer at high speed, i.e., the sputtering phenomenon. Therefore, the wafer gets serious physical damages. When the plasma density in the reaction area is not uniform or is abnormally high, the thin film formed on the wafer get the plasma charging damages. These problems bring about serious trouble in the semiconductor devices.

Furthermore, since the remote plasma generators are additionally installed in the thin film deposition apparatus, the cost of thin film deposition apparatus increases and the cost of production are also raised. Additionally, since the pressure of the first and/or second gases introduced into the chamber has to be limited on account of plasma excitation and maintenance, the productivity decreases when forming the thin film on the wafer.

### SUMMARY OF THE INVENTION

Accordingly, the present invention is directed to a thin film deposition apparatus and method that substantially overcome one or more of the problems due to limitations and disadvantages of the related art.

To overcome the problems described above, the present invention provides a thin film deposition apparatus and method that prevent a wafer from the thermal impact.

An object of the present invention is to provide a thin film deposition apparatus and method that form a thin film without any damages.

Additional features and advantages of the invention will be set forth in the description that follows, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the present invention, as embodied and broadly described, a thin film deposition apparatus includes a chamber where a wafer is loaded; a gas supplier containing a plurality of gases, the gas supplier connected with the chamber through at least a gas inflow pipe so as to supplying the plurality of gases into the chamber; an airtight reaction room in the chamber where the plurality of gases are reaction with one another so as to form a thin film on the wafer; and a gas pre-treatment device in the gas supplier, the gas pre-treatment device thermal-treating at least one of the plurality of gases at a temperature in the range of more than 300 to less than 2000 degrees centigrade; wherein the gas pre-treatment device is connected to at least a connecting pipe. The gas pre-treatment device includes a gas heater heating up at a temperature in the range of 300 to 2000 degrees centigrade, and a packing filter having a plurality of air gaps therein and surrounding the gas heater so as to dissipate heat generated from the gas heater. The gas pre-treatment device serves to activate the gas passing the packing filter into radicals. The gas heater includes an electrical resistance heating system therein. The packing filter is a plurality of beads each having a diameter of less than 2 millimeters, or a grid of wire mesh. The packing filter is made of a heat-resistant material, such as a ceramic material.

The above-mentioned gas supplier includes a first gas container storing a first gas; a first connecting pipe connecting the first gas container to the chamber; a first mass flow controller controlling a flow rate of first gas passing through the first connecting pipe; a second connecting pipe connecting the first gas container to the chamber; a second mass flow controller controlling a flow rate of first gas passing through the second connecting pipe; a second gas container storing a second gas; a third connecting pipe connecting the second gas container to the chamber; and a third mass flow controller controlling a flow rate of second gas passing through the third connecting pipe; wherein the gas pre-treatment device is connected to the first connecting pipe and thermal-treating the first gas passing through the first connecting pipe at the temperature in the range of more than 300 to less than 2000 degrees centigrade. The first mass flow controller is installed in the first connecting pipe between the first gas container and the gas inflow pipe. The gas pre-treatment device is installed in the first connecting pipe between the first mass flow controller and the gas inflow pipe. The gas pre-treatment device includes a gas heater heating up at a temperature in the range of 300 to 2000 degrees centigrade, and a packing filter having a plurality of air gaps therein and surrounding the gas heater so as to dissipate heat generated from the gas heater. The gas pre-treatment device serves to activate the first gas passing the packing filter into radicals. The gas heater includes an electrical resistance heating system therein. The packing filter is a plurality of beads each having a diameter of less than 2 millimeters, or a grid of wire mesh. The packing filter is made of a heat-resistant material, such as a ceramic material. The second mass flow controller is installed in the second connecting pipe between the first gas container and the gas inflow pipe, and the third mass flow controller is installed in the third connecting pipe between the second gas container and the gas inflow pipe. The first gas is selected from a group consisting of NH₃, N₂O and O₂, while the second gas is selected from a group consisting of SiH₄ and Si₂H₆.

In another aspect of the present invention, a thin film deposition apparatus includes a chamber where a wafer is loaded; a gas supplier connected with the chamber through at least a gas inflow pipe so as to supplying a plurality of gases into the chamber; an airtight reaction room in the chamber where the plurality of gases are reaction with one another so as to form a thin film on the wafer; a first gas container in the gas supplier, the first gas container storing a first gas; a first connecting pipe connecting the first gas container to the gas inflow pipe; a first mass flow controller controlling a flow rate of first gas passing through the first connecting pipe; a second connecting pipe connecting the first gas container to the gas inflow pipe; a second mass flow controller controlling a flow rate of first gas passing through the second connecting pipe; a second gas container storing a second gas; a third connecting pipe connecting the second gas container to the gas inflow pipe; a third mass flow controller controlling a flow rate of second gas passing through the third connecting pipe; a gas pre-treatment device in the gas supplier, the gas pre-treatment device thermal-treating the first gas passing through the first connecting pipe at a temperature in the range of more than 300 to less than 2000 degrees centigrade; a gas heater installed in the gas pre-treatment device, the gas heater heating up at a temperature in the range of 300 to 200 degrees centigrade; a packing filter installed in the gas pre-treatment device, the packing filter surrounding the gas heater and having a plurality of air gaps therein so as to dissipate heat generated from the gas heater.

In another aspect of the present invention, a thin film deposition method uses a plurality of source gases each of that passes through a connecting pipe into a chamber. The thin film deposition method includes the steps of loading a wafer on the chamber; thermal-treating at least one of the plurality of source gases using a gas pre-treatment device in the connecting pipe at a temperature in the range of more than 300 to less than 2000 degrees centigrade; and reacting the thermal-treated source gas with the other source gases in the chamber so as to form the thin film on the wafer. The gas pre-treatment device includes a gas heater heating up at a temperature in the range of 300 to 2000 degrees centigrade, and a packing filter having a plurality of air gaps therein and surrounding the gas heater so as to dissipate heat generated from the gas heater. The gas pre-treatment device serves to activate the source gas passing the packing filter into radicals. The gas heater includes an electrical resistance heating system therein. The packing filter is a plurality of beads each having a diameter of less than 2 millimeters, or a grid of wire mesh. The packing filter is made of a heat-resistant material, such as a ceramic material. The plurality of source gases includes first and second gases. The first gas is selected from a group consisting of NH3, N2O and O2, and thermal-treated by the gas pre-treatment device. The second gas is selected from a group consisting of SiH4 and Si2H6.

It is to be understood that both the foregoing general description and the following detailed description are exemplary and explanatory and are intended to provide further explanation of the invention as claimed.

The accompanying drawings are included to provide a further understanding of the invention and are incorporated in and constitute a part of this specification, illustrate one embodiment of the invention and together with the description serve to explain the principles of the invention.

### BRIEF DESCRIPTION OF THE DRAWINGS

The accompanying drawings, which are included to provide a further understanding of the invention and are incorporated in and constitute a part of this application, illustrate embodiment of the invention and together with the description serve to explain the principle of the invention.

In the drawings:

FIG. 1 schematically illustrates a thin film deposition apparatus diagram for the CVD according to a conventional art;

FIG. 2 schematically illustrates a thin film deposition apparatus diagram according to the present invention;

FIG. 3A is an enlarged cross-sectional view illustrating a gas pre-treatment device according to the present invention;

FIG. 3B is an enlarged cross-sectional view illustrating a modification of a gas pre-treatment device according to the present invention; and

FIG. 4 is a graph showing etch rate-dependence of gas heater temperature.

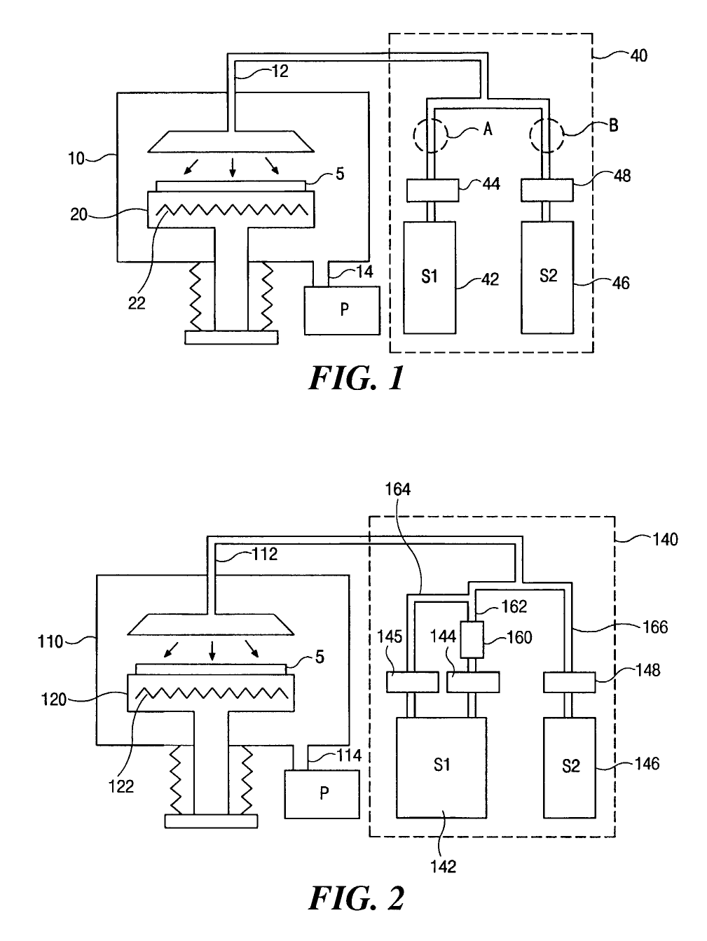

### DETAILED DESCRIPTION OF ILLUSTRATED EMBODIMENTS

Reference will now be made in detail to illustrated embodiment of the present invention, examples of which are shown in the accompanying drawings. Wherever possible, the same reference numbers will be used throughout the drawings to refer to the same or like parts.

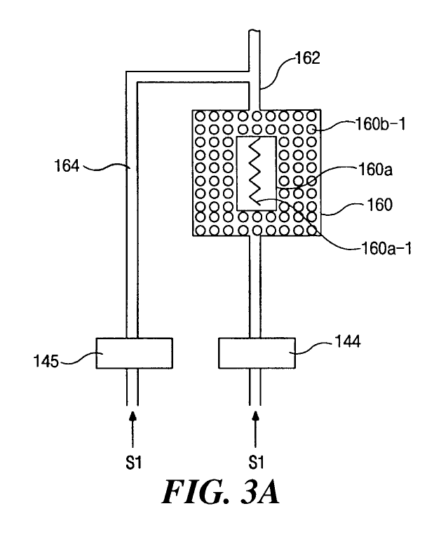

FIG. 2 schematically illustrates a thin film deposition apparatus diagram according to the present invention. As shown in FIG. 2, the thin film deposition apparatus of the present invention includes a chamber 110 and a gas supplier 140. The chamber 110 has an airtight reaction room therein and a wafer 5 is mounted on a chuck 120 inside the airtight reaction room. The gas supplier 140 serves to contain a plurality of source gases that will be introduced into the reaction room of the chamber 110.

The chamber 110 is connected to the gas supplier 140 through a gas inflow pipe 112. Meanwhile, a gas outflow pipe 114 is connected to the bottom of the chamber 110, and a decompression device, such as a pump P, is connected to the chamber 110 through the gas outflow pipe 114.

In the gas supplier 140, there are first and second gas containers 142 and 146 which store first and second gases S1 and S2, respectively. The first gas container 142 is connected to the gas inflow pipe 112 through both first and second connecting pipes 162 and 164, while the second gas container 146 is connected to the gas inflow pipe 112 through a third connecting pipe 166. First to third mass flow controllers (MFCs) 144, 145 and 148 are located in the first to third connecting pipes 162, 164 and 166, respectively. The flow rate of first gas S1 is controlled by both the first and second MFCs 144 and 145, and the third MFC 148 controls the flow rate of second gas S2. Namely, the first to third MFCs 144, 145 and 148 handle the flow rate of the source gases.

According the present invention, a gas pre-treatment device 160 is connected between the first MFC 144 and the gas inflow pipe 112 or between the second MFC 145 and the gas inflow pipe 112. Although FIG. 2 shows that the gas pre-treatment device 160 is positioned in the first connecting pipe 162 between the first MFC 144 and the gas inflow pipe 112, the gas pre-treatment device 160 can be located in the second connecting pipe 164 between the second MFC 145 and the gas inflow pipe 112. At this point, it is self-evident in the present invention that the gas pre-treatment device 160 is in the third connecting pipe 166 between the third MFC 148 and the gas inflow pipe 112. If there is a third gas container storing a third gas in the gas supplier 140, a fourth connecting pipe can connect the third gas container to the gas inflow pipe 112, and a fourth MFC can be located in the fourth connecting pipe between the third gas container and the gas inflow pipe 112. Accordingly, the gas pre-treatment device 160 of the present invention can be installed in one or all of the connecting pipes between the MFC and the gas inflow pipe 112. Hereinafter, it is assumed that the gas pre-treatment device 160 is installed in the first connecting pipe 162 between the first MFC 144 and the gas inflow pipe 112, as shown in FIG. 2. The gas pre-treatment device 160 of FIG. 2 pre-heats up the first gas S1 at a temperature from 300 to 2000 degrees centigrade in order to activate the first gas S I into the radical.

In the meantime, the airtight reaction room of the chamber 110 should be kept at a high temperature in order to promote the gas reaction. For the high temperature atmosphere in the airtight reaction room, the chuck 120 includes a first heater 122 that heats up the wafer 5 and the airtight reaction room. The atmospheric temperature in the airtight reaction room of the chamber 110 can vary depending on the gases, gas reaction and reaction product.

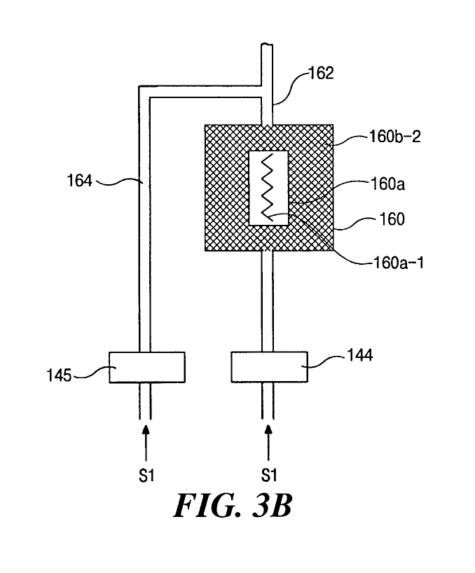

FIG. 3A is an enlarged cross-sectional view illustrating the gas pre-treatment device 160 according to the present invention, and FIG. 3B is an enlarged cross-sectional view illustrating a modification of the gas pre-treatment device 160 according to the present invention.

As shown in FIGS. 3A and 3B, the gas pre-treatment device 160 of the present invention is located between the first MFC 144 and the gas inflow pipe 112, and has a pipe or tube shape, i.e., a cylindrical shape. Especially, the gas pre-treatment device 160 includes a gas heater 160a where a second heater 160a-1 is installed. The second heater 160a-1 heats up at a temperature of 300 to 2000 degrees centigrade. The gas pre-treatment device 160 includes a packing filter 160b-1 or 160b-2 therein, which surrounds the gas heater 160a. The second heater 160a-1 has a same electrical resistance heating system as the first heater 122 (see FIG. 2) so that the second heater 160a-1 can have a power source jointly with the first heater 122.

The packing filter 160b-1 or 160b-2 surrounding the gas heater 160a has a plurality of air gaps therein and serves to maximize thermal contact area. Therefore, the gas heater 160a can effectively dissipate heat generated by the second heater 160a-1 using such a packing filter 160b-1 or 160b-2, and then the first gas S1 passing through the gas pre-treatment device 160 can efficiently receives thermal energy from the gas heater 160a. In the present invention, the packing filter is a plurality of small beads 160b-1 as shown in FIG. 3A, or a grid of wire mesh 160b-2 as shown in FIG. 3B. The plurality of small beads 160b-1 of FIG. 3A fill the gas pre-treatment device 160 and surround the gas heater 160a. The grid of wire mesh 160b-2 of FIG. 3B is formed by winding the wires around the gas heater 160a. Heat-resistant materials are used as a material for the packing filters 160b-1 and 160b-2 such that the packing filters 160a-1 and 160b-2 do not react with the source gases. Advisably, the packing filters 160b-1 and 160b-2 are made of ceramic. The plurality of small beads 160b-1 serve not only to transfer the heat to the first gas S1 but also to prevent the heat dissipation outside the gas pre-treatment device 160. The diameter of the beads 160b-1 is as good as it is smaller, but should not interrupt the gas flow. Advisably, the diameter of the beads 160b-1 is less than 2 millimeters and the optimum size of the beads 160b-1 is 1 millimeter in diameter.

According to the present invention, the first gas S1 passing through the gas pre-treatment device 160 is heated up to more than 300 and less than 2000 degrees centigrade by the second heater 160a-1 installed in the gas heater 160a. Thus, due to the maximized contact area, the first gas S1 efficiently receives thermal energy from the gas heater 160a and the molecular structure of the first gas S1 is easily decomposed to make radicals of the first gas that have the lower activation energy.

Meanwhile, as aforementioned with reference to FIG. 2, the first gas container 142 is connected to the gas inflow pipe 112 though the first and second connecting pipes 162 and 164. Further, the first MFC 144 is on the first connecting pipe 162 and the second MFC 145 is on the second connecting pipe 164. Thus, the first and second MFCs 144 and 145 control the flow rate of the firs gas S1 so as to supply the first gas S1 into the chamber 110 through the first and second connecting pipes 162 and 164.

The thin film deposition process that uses the above-mentioned deposition apparatus will be explained hereinafter. When the wafer 5 is mounted on the chuck 120 of the chamber 110, the chamber is made airtight. Thereafter, the first heater 122 installed in the chuck 120 heats up and simultaneously the first and second gases S1 and S2 are introduced into the chamber 110 by the first to third MFCs 144, 145 and 148. At this time, the first gas S1 passes throughout the first and second connecting pipes 162 and 164 by the first and second MFCs 144 and 145, respectively. The first gas S1 passing through the first connecting pipe 162 by the first MFC 144 is heated up by the gas pre-treatment device 160 at a temperature of more than 300 and less than 2000 degrees centigrade, and thus the first gas S1 passing through the gas pre-treatment device 160 is changed into the radicals. As a result, the first gas S1 passing through the first connecting pipe 162 is provided as radicals, while the first gas S1 passing through the second connecting pipe 164 is provided as it is without any decomposition. The second gas S2 is supplied into the chamber 110 through the third connecting pipe 166. So the first gas S1, the radicals of first gas, and the second gas S2 coexist in the airtight reaction room of the chamber 110, and then these gases and radicals react with one another in the airtight reaction room to form the reaction product on the wafer 5 as a thin film.

In the above-mentioned deposition process, if the thin film deposited on the wafer 5 is nitride film or oxide film, the first gas S1 is selected from a group consisting of NH₃, N₂O and O₂, or from a group consisting of SiH₄ and Si₂H₆. Among these gases, NH₃, N₂O and O₂ are needed to be activated by passing the gas pre-treatment device 160, if one of these gases is used for the first gas S1.

In the meantime, it is expected and possible that all the first gas S1 passes through the first connecting pipe 162 and through the gas pre-treatment device 160 in order to change all the first gas S1 into the radicals. However, this reduces the productivity. For example, NH₃ can be converted into N, N₂, H, H₂, NH and/or NH₂ by the thermal decomposition. Among these gases N, N₂, H, H₂, NH and NH₂, the N₂ gas does not contribute to the thin film deposition process. If the gaseous ratio of N₂ increases, the productivity of thin film will be reduced. Therefore, it is recommended that the first and second connecting pipes 162 and 164 are connected to the first gas container 142 to supply the first gas S1 into the chamber 110 separately. The mixture rate of the first gas S1 to the radicals of first gas is illustrated as the following Table 1.

TABLE 1

| P-NH₃ | L-NH₃ | THK | DR | Unif | | WR | |
|---|---|---|---|---|---|---|---|
| (sccm) | (sccm) | (Å) | (Å/min) | (%) | RI | (Å/min) | N-H/Si-H PR |
| 0 | 2000 | 976.2 | 325.4 | 3.74 | 2.009 | 19.3 | 0.35 |
| 500 | 1500 | 911.3 | 303.8 | 3.41 | 2.027 | 15.9 | 0.23 |
| 1000 | 1000 | 842.5 | 280.8 | 3.38 | 2.038 | 13.6 | 0.21 |
| 1500 | 500 | 846.2 | 282.1 | 3.28 | 2.034 | 14.1 | 0.20 |
| 2000 | 0 | 710.8 | 236.9 | 4.66 | 2.054 | 10.9 | 1.00 |

For the result shown in Table 1, NH₃ is used as a first gas S1 and SiH₄ is used as a second gas S2, so that a silicon nitride thin film is deposited on the wafer. During the experiment to get the result shown in Table 1, the flow rate of the first gas S1 into the chamber is fixed at 2000 sccm in order to comprehend the excellent mixture rate of the first gas S1 to the radicals of first gas. P-NH₃ in Table 1 shows a quantity of NH₃ passing through the gas pre-treatment device 160, and L-NH₃ in Table 1 shows a quantity of NH₃ passing through the second connecting pine 164. The gas heater 160a in the gas pre-treatment device 160 has a temperature of 1100 degrees centigrade, the chamber 110 has a pressure of 20 Torr, and the process temperature in the chamber 110 is 700 degrees centigrade. The N₂ gas having a flow rate of 1000 sccm is used for the carrier gas, and the deposition process is carried out for about 180 seconds. After the experiment, the characteristics of the deposited thin film are examined as the following five items:

1. THK: Showing the thickness of the deposited thin film. The thickness THK of the deposited thin film is measured in the five points (at the central point of the deposited thin film, up-and-down points, and right-and-left points) on the deposited thin film. As the thickness increases, the productivity of the thin film becomes higher.

2. DR: Deposition Rate (DR) showing the thickness of deposited thin film per minute. The value of deposition rate is also measured in the five points on the deposited thin film. As the deposition rate increases, the productivity of the thin film becomes higher.

3. Unif: Showing the uniformity of the deposited thin film. As the uniformity Unif becomes closer to zero (0), the deposited thin film becomes superior.

4. RI: Refraction Index (RI) of the deposited thin film. In view of the SiN thin film, when the refraction index value ranges from 1.8 to 2.0, it is quite satisfactory. Within that range of 1.8 to 2.0, the greater the refraction index value the greater the thin film quality.

5. WR: Wet-etch Rate. The wet-etch rate WR is a value that shows the comparison of the wet-etched thin film with the oxidized film. The wet-etch rate WR shows the etching speed of the deposited thin film as compared to the thermal oxidized film. In this experiment, the etching solution is a HF solution having a ratio of 100 to 1. The etching experiment is performed for about 20 minutes.

6. IR-PR: IR Peak Ratio. The greater the N—H/Si—H peak ratio the greater the thin film quality.

As a result shown in Table 1, when all the first gas S1, NH₃, passes through the gas pre-treatment device 160 and then is introduced into chamber 110, the productivity of the thin film decreases. However, the thin film qualities, such as WR and IR-PR, are improved. Although the above-mentioned experiment is conducted under the temperature of 700 degrees centigrade in the reaction room of the chamber 110, the same result is expected when the process temperature is less than 600 degrees centigrade in the reaction room of the chamber 110. Accordingly in the present invention, since the gas pre-treatment device 160 is utilized in the thin film deposition apparatus, the process temperature in the reaction room can be reduced dramatically and the thermal budget into the wafer 5 is minimized.

On the contrary, when all the first gas S1, NH₃, passes through the second connecting pipe 164 and is supplied into the chamber 110 as it is, the thin film quality is deteriorated although the productivity a bit increases. Especially, when the process temperature in the reaction room is less than 700 degrees centigrade, the productivity of the thin film is further reduced. Therefore, when all the first gas S1, NH₃, passes through the second connecting pipe 164, the process temperature in the reaction room should be maintained at a temperature of more than 700 degrees centigrade and the thermal budget onto the wafer is not avoided.

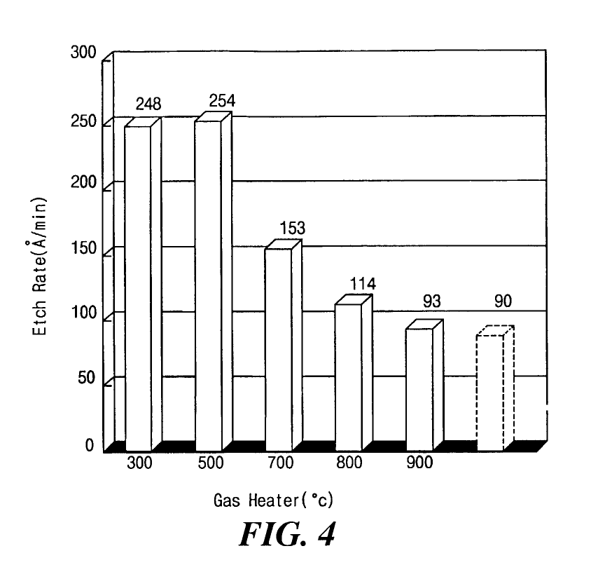

FIG. 4 is a graph showing etch rate-dependence of gas heater temperature. In order to get the result shown in FIG. 4, the pressure in the reaction room of the chamber 110 was about 18 Torr, and the temperature in the reaction room was about 650 degrees centigrade. When the temperature of the gas heater 160 ranges from 300 to 900 degrees centigrade, the etch rate of the thin film is measured. The flow rate of NH₃ gas is 1000 sccm, and the flow rate of SIH₄ is 50 sccm. Furthermore, the etch rate shown FIG. 4 is measured when the Si₃N₄ thin film deposited on the wafer is etched by H₃PO₄ at a temperature of 160 degrees centigrade for 270 seconds.

In the graph shown in FIG. 4, the x-axis represents the temperature of the gas pre-treatment device 160 through which the NH₃ gas passes, and the y-axis represents the etch rate per minute. The bar graph illustrated by the dotted line on the right side of the graph shows the etch rate according to the conventional art under the same conditions, i.e., the NH₃ flow rate of 1000 sccm, the SiH₄ flow rate of 50 sccm, and the reaction room pressure of 18 Torr. Furthermore, the etch rate shown by the dotted bar graph of FIG. 4 is measured when the first heater 122 has a temperature of 750 degrees centigrade and when the deposited thin film is etched by H₃PO₄ under a temperature of 160 degrees centigrade for 270 seconds.

With reference to the graph shown in FIG. 4, when the gas heater 160a of the gas pre-treatment 160 has the temperature of 900 degrees centigrade, the thin film deposited by the present invention has the same characteristics as the thin film conventionally deposited under the temperature of about 750 degrees centigrade even if the reaction room of the chamber 110 has the temperature of more than 600 to less then 700 degrees centigrade (advisably, about 650 degrees centigrade).

Accordingly, when forming the thin film according to the present invention, it is recommended that the first and second MFCs 144 and 145 adjust the gas flow rate at the same rate. Namely, the first and second MFCs 144 and 145 distribute the first gas S1 at the same flow rate. Therefore, according the to present invention, the thermal budget onto the wafer is minimized, and the productivity and characteristics of the thin film are improved.

Now with reference to FIG. 2, the thin film deposition process will be explained briefly. When the wafer 5 is first loaded on the chuck 120, the first heater 122 heats up to supply appropriate heat to the wafer 5. At this time, the temperature of the first heat 122 in the present invention is much lower compared to the conventional chemical vapor deposition process. Thereafter, the first and second gases S1 and S2 are supplied into the chamber 110 through the first and second connecting pipes 162 and 164 and through the third connecting pipe 166, respectively. At this time of supplying the source gases, the flow rate of the first gas S1 is controlled by the first and second MFCs 144 and 145, while the flow rate of the second gas S2 is controlled by the third MFC 148. Specially, the first MFC 144 controls the flow rate of the first gas S1 that passes through the gas pre-treatment device 160. When passing through the gas pre-treatment device 160, the first gas S1 passes throughout the packing filter 160b-1 or 160b-2 (see FIGS. 3A and 3B) and is heated up to be activated into radicals. Then, the radicals of the first gas are introduced into the chamber 110 through the gas inflow pipe 112 with the first and second gases S1 and S2. Since the activated radical gas has a low activation energy, the chemical reaction is easily conducted at a relatively low temperature in the reaction room as compared to the conventional process. In the reaction room of the chamber 110, the radicals of first gas coexist with the first gas S1 and the second gas S2. The chemical reaction of these coexisting gases in the reaction room forms the thin film on the wafer 5.

Although not shown in FIGS. 2 and 3A-3B, a cooling system that prevents the heat generated from the second heater 160a-1 can be formed around the gas pre-treatment device 160 in order to maintain the safety during the process. Further, it will be apparent to those skilled in the art that the gas pre-treatment device of the present invention can be installed in the others connecting pipes. Although the present invention having the gas pre-treatment device 160 is explained focusing on the chemical vapor deposition, the present invention can be adopted in other apparatuses manufacturing the semiconductor devices. Namely, the present invention can be applied in such an ALD (Atomic Layer Deposition) or a Plasma Enhanced Chemical Vapor Deposition.

In the present invention, the gas heater in the gas pre-treatment device heats up at a temperature of from 300 to 2000 degrees centigrade, and the gas pre-treatment includes the packing filter surrounding the gas heater. Therefore, the source gas is easily activated and then supplied into the chamber. Additionally, since the thin film deposition process is conducted at a relatively low temperature in the reaction room according to the present invention, the thermal budget onto the wafer is minimized, thereby obtaining the improved thin film.

Moreover, since the present invention provides the gas pre-treatment device having a simple structure, the fabrication of the semiconductor devices can be simplified. By way of controlling the flow rates and pressures of the first gas using the first and second MFCs, the amount of the activated gas can be controlled freely and thus the productivity and quantity of the deposited thin film is adjustable as freely as it does.

In the present invention, since the second heater installed in the gas pre-treatment device has the same electrical resistance heating system as the first heater installed in the chuck, the second heater can have the power source jointly with the first heater, thereby simplifying the deposition apparatus and reducing the cost of production. Furthermore, the packing filter, such as the plurality of beads and the grid of wire mesh, increases the thermal contact area of the source gas, the gas activation is easily carried out. As mentioned before, the packing filter is made of ceramic or other heat-resistant materials, so the gas activation process is safely performed.

It will be apparent to those skilled in the art that various modifications and variations can be made in the capacitor and the manufacturing method thereof of the present invention without departing from the spirit or scope of the inventions. Thus, it is intended that the present invention cover the modifications and variations of this invention provided they come within the scope of the appended claims and their equivalents.

What is claimed is:

1. A thin film deposition apparatus, comprising:
a chamber where a wafer is loaded;
a gas supplier containing a plurality of gases, the gas supplier connected with the chamber through at least a gas inflow pipe so as to supplying the plurality of gases into the chamber;
an airtight reaction room in the chamber where the plurality of gases are reaction with one another so as to form a thin film on the wafer; and
a gas pre-treatment device in the gas supplier, the gas pre-treatment device thermal-treating at least one of the plurality of gases at a temperature in the range of more than 300 to less than 2000 degrees centigrade;
wherein the gas pre-treatment device is connected to at least a connecting pipe.

2. The apparatus of claim 1, wherein the gas pre-treatment device includes a gas heater heating up at a temperature in the range of 300 to 2000 degrees centigrade, and a packing filter having a plurality of air gaps therein and surrounding the gas heater so as to dissipate heat generated from the gas heater.

3. The apparatus of claim 2, wherein the gas pre-treatment device serves to activate the gas passing the packing filter into radicals.

4. The apparatus of claim 2, wherein the gas heater includes an electrical resistance heating system therein.

5. The apparatus of claim 2, wherein the packing filter is a plurality of beads each having a diameter of less than 2 millimeters.

6. The apparatus of claim 2, wherein the packing filter is a grid of wire mesh.

7. The apparatus of claim 2, wherein the packing filter is made of a heat-resistant material.

8. The apparatus of claim 2, wherein the packing filter is made of a ceramic material.

9. The apparatus of claim 1, wherein the gas supplier comprises:
a first gas container storing a first gas;
a first connecting pipe connecting the first gas container to the chamber;
a first mass flow controller controlling a flow rate of first gas passing through the first connecting pipe;
a second connecting pipe connecting the first gas container to the chamber;
a second mass flow controller controlling a flow rate of first gas passing through the second connecting pipe;
a second gas container storing a second gas;
a third connecting pipe connecting the second gas container to the chamber; and
a third mass flow controller controlling a flow rate of second gas passing through the third connecting pipe;
wherein the gas pre-treatment device is connected to the first connecting pipe and thermal-treating the first gas passing through the first connecting pipe at the temperature in the range of more than 300 to less than 2000 degrees centigrade.

10. The apparatus of claim 9, wherein the first mass flow controller is installed in the first connecting pipe between the first gas container and the gas inflow pipe.

11. The apparatus of claim 10, wherein the gas pre-treatment device is installed in the first connecting pipe between the first mass flow controller and the gas inflow pipe.

12. The apparatus of claim 11, wherein the gas pre-treatment device includes a gas heater heating up at a temperature in the range of 300 to 2000 degrees centigrade, and a packing filter having a plurality of air gaps therein and surrounding the gas heater so as to dissipate heat generated from the gas heater.

13. The apparatus of claim 12, wherein the gas pre-treatment device serves to activate the first gas passing the packing filter into radicals.

14. The apparatus of claim 12, wherein the gas heater includes an electrical resistance heating system therein.

15. The apparatus of claim 12, wherein the packing filter is a plurality of beads each having a diameter of less than 2 millimeters.

16. The apparatus of claim 12, wherein the packing filter is a grid of wire mesh.

17. The apparatus of claim 12, wherein the packing filter is made of a heat-resistant material.

18. The apparatus of claim 12, wherein the packing filter is made of a ceramic material.

19. The apparatus of claim 9, wherein the second mass flow controller is installed in the second connecting pipe between the first gas container and the gas inflow pipe.

20. The apparatus of claim 9, wherein the third mass flow controller is installed in the third connecting pipe between the second gas container and the gas inflow pipe.

21. The apparatus of claim 9, wherein the first gas is selected from a group consisting of NH₃, N₂O and O₂.

22. The apparatus of claim 9, wherein the second gas is selected from a group consisting of SiH₄ and Si₂H₆.

23. A thin film deposition apparatus, comprising:
a chamber where a wafer is loaded;
a gas supplier connected with the chamber through at least a gas inflow pipe so as to supplying a plurality of gases into the chamber;
an airtight reaction room in the chamber where the plurality of gases are reaction with one another so as to form a thin film on the wafer;
a first gas container in the gas supplier, the first gas container storing a first gas;
a first connecting pipe connecting the first gas container to the gas inflow pipe;
a first mass flow controller controlling a flow rate of first gas passing through the first connecting pipe;
a second connecting pipe connecting the first gas container to the gas inflow pipe;
a second mass flow controller controlling a flow rate of first gas passing through the second connecting pipe;
a second gas container storing a second gas;
a third connecting pipe connecting the second gas container to the gas inflow pipe;
a third mass flow controller controlling a flow rate of second gas passing through the third connecting pipe;
a gas pre-treatment device in the gas supplier, the gas pre-treatment device thermal-treating the first gas passing through the first connecting pipe at a temperature in the range of more than 300 to less than 2000 degrees centigrade;
a gas heater installed in the gas pre-treatment device, the gas heater heating up at a temperature in the range of 300 to 200 degrees centigrade;
a packing filter installed in the gas pre-treatment device, the packing filter surrounding the gas heater and having a plurality of air gaps therein so as to dissipate heat generated from the gas heater.

24. The apparatus of claim 23, wherein the gas pre-treatment device serves to activate the first gas passing the packing filter into radicals.

25. The apparatus of claim 23, wherein first mass flow controller is installed in the first connecting pipe between the first gas container and the gas inflow pipe.

26. The apparatus of claim 23, wherein the gas pre-treatment device is installed in the first connecting pipe between the first mass flow controller and the gas inflow pipe.

27. The apparatus of claim 23, wherein the gas heater includes an electrical resistance heating system therein.

28. The apparatus of claim 23, wherein the packing filter is a plurality of beads each having a diameter of less than 2 millimeters.

29. The apparatus of claim 23, wherein the packing filter is a grid of wire mesh.

30. The apparatus of claim 23, wherein the packing filter is made of a heat-resistant material.

31. The apparatus of claim 23, wherein the packing filter is made of a ceramic material.

32. The apparatus of claim 23, wherein the second mass flow controller is installed in the second connecting pipe between the first gas container and the gas inflow pipe.

33. The apparatus of claim 23, wherein the third mass flow controller is installed in the third connecting pipe between the second gas container and the gas inflow pipe.

34. The apparatus of claim 23, wherein the first gas is selected from a group consisting of NH₃, N₂O and O₂.

35. The apparatus of claim 23, wherein the second gas is selected from a group consisting of SiH₄ and Si₂H₆.

36. A thin film deposition method using a plurality of source gases each of that passes through a connecting pipe into a chamber, comprising the steps of:
loading a wafer on the chamber;
thermal-treating at least one of the plurality of source gases using a gas pre-treatment device in the connecting pipe at a temperature in the range of more than 300 to less than 2000 degrees centigrade; and
reacting the thermal-treated source gas with the other source gases in the chamber so as to form the thin film on the wafer.

37. The method of claim 36, wherein the gas pre-treatment device includes a gas heater heating up at a temperature in the range of 300 to 2000 degrees centigrade, and a packing filter having a plurality of air gaps therein and surrounding the gas heater so as to dissipate heat generated from the gas heater.

38. The method of claim 37, wherein the gas pre-treatment device serves to activate the source gas passing the packing filter into radicals.

39. The method of claim 37, wherein the gas heater includes an electrical resistance heating system therein.

40. The method of claim 37, wherein the packing filter is a plurality of beads each having a diameter of less than 2 millimeters.

41. The method of claim 37, wherein the packing filter is a grid of wire mesh.

42. The method of claim 37, wherein the packing filter is made of a heat-resistant material.

43. The method of claim 37, wherein the packing filter is made of a ceramic material.

44. The method of claim 36, wherein the plurality of source gases includes first and second gases.

45. The method of claim 44, wherein the first gas is selected from a group consisting of NH₃, N₂O and O₂, and thermal-treated by the gas pre-treatment device.

46. The method of claim 44, wherein the second gas is selected from a group consisting of SiH₄ and Si₂H₆.
